(19) United States
(12) Patent Application Publication
(10) Pub. No.: US 2024/0021654 A1
(43) Pub. Date: Jan. 18, 2024

(54) METHOD FOR FORMING PHOTOELECTRIC CONVERSION REGION OF IMAGE SENSING DEVICE

(71) Applicant: SK hynix Inc., Icheon-si (KR)

(72) Inventor: Kang Yeon LEE, Icheon-si (KR)

(21) Appl. No.: 18/075,676

(22) Filed: Dec. 6, 2022

(30) Foreign Application Priority Data
Jul. 15, 2022 (KR) 10-2022-0087288

(51) Int. Cl. H01L 27/146

(52) U.S. Cl. CPC H01L 27/14689; H01L 27/14643

(57) ABSTRACT

A method for forming a photoelectric conversion region of an image sensing device includes determining a thickness of a substrate and a capacitance of a photoelectric conversion region of an image sensing pixel corresponding to a desired performance of the image sensing pixel, determining a size of a desired photoelectric conversion region for the image sensing pixel based on the determined thickness of the substrate and the determined capacitance of the photoelectric conversion region, determining a first ion implantation energy suitable for implanting impurities into a predetermined depth in the substrate, determining a thickness of a mask pattern corresponding to the first ion implantation energy, and determining at least one second ion implantation energy suitable for implanting the impurities into the substrate for forming a plurality of sub-photoelectric conversion regions at different depths that collectively form the desired photoelectric conversion region.

### CROSS-REFERENCE TO RELATED APPLICATION

This patent document claims the priority and benefits of Korean patent application No. 10-2022-0087288, filed on Jul. 15, 2022, which is incorporated by reference in its entirety as part of the disclosure of this patent document.

### TECHNICAL FIELD

The technology and implementations disclosed in this patent document generally relate to an image sensing device.

### BACKGROUND

An image sensor is used in electronic devices to convert optical images into electrical signals. With the recent development of automotive, medical, computer and communication industries, the demand for highly integrated, higher-performance image sensors has been rapidly increasing in various electronic devices such as digital cameras, camcorders, personal communication systems (PCSs), video game consoles, surveillance cameras, medical micro-cameras, robots, etc.

The image sensing device may be roughly divided into CCD (Charge Coupled Device) image sensing devices and CMOS (Complementary Metal Oxide Semiconductor) image sensing devices. The CCD image sensing devices offer a better image quality, but they tend to consume more power and are larger as compared to the CMOS image sensing devices. The CMOS image sensing devices are smaller in size and consume less power than the CCD image sensing devices. Furthermore, CMOS sensors are fabricated using the CMOS fabrication technology, and thus photosensitive elements and other signal processing circuitry can be integrated into a single chip, enabling the production of miniaturized image sensing devices at a lower cost. For these reasons, CMOS image sensing devices are being developed for many applications including mobile devices.

### SUMMARY

Various embodiments of the disclosed technology relate to a method for uniformly maintaining a critical dimension (CD) of a photoelectric conversion region while deeply forming the photoelectric conversion region.

In some embodiments of the disclosed technology, a method for forming a photoelectric conversion region of an image sensing device may include determining a thickness of a substrate and a capacitance of a photoelectric conversion region of an image sensing pixel corresponding to a desired performance of the image sensing pixel, determining a size of a desired photoelectric conversion region for the image sensing pixel based on the determined thickness of the substrate and the determined capacitance of the photoelectric conversion region, determining a first ion implantation energy suitable for implanting impurities into a predetermined depth in the substrate, determining a thickness of a mask pattern corresponding to the first ion implantation energy, and determining at least one second ion implantation energy suitable for implanting the impurities into the substrate for forming a plurality of sub-photoelectric conversion regions at different depths that collectively form the desired photoelectric conversion region.

In some embodiments of the disclosed technology, a method for forming a photoelectric conversion region of an image sensing device may include forming a first mask pattern defining a photoelectric conversion region over a first surface of a substrate, implanting impurities from the first surface of the substrate into a first region in the substrate using the first mask pattern as an implantation mask, forming a second mask pattern defining the photoelectric conversion region over a second surface opposite to the first surface of the substrate, and implanting impurities from the second surface of the substrate into a second region in the substrate using the second mask pattern as an implantation mask. Each of the first mask pattern and the second mask pattern may be formed to have a minimum thickness that prevents the corresponding impurities from penetrating a material layer of the first mask pattern and a material layer of the second mask pattern when the impurities are implanted into the substrate at a first ion implantation energy using the first mask pattern and the second mask pattern as implantation mask, respectively.

In some embodiments of the disclosed technology, a method for forming a photoelectric conversion region of an image sensing device may include calculating a thickness of a substrate and a capacitance of a photoelectric conversion region, each of which corresponds to a predetermined pixel performance, calculating a size of the photoelectric conversion region based on the calculated substrate thickness and the calculated capacitance of the photoelectric conversion region, calculating a first ion implantation energy required to implant impurities into a center portion of the photoelectric conversion region, calculating a thickness of a mask pattern corresponding to the first ion implantation energy, and dividing the photoelectric conversion region into a plurality of sub-photoelectric conversion regions, and calculating a second ion implantation energy required to implant the impurities into each sub-photoelectric conversion region.

In some embodiments of the disclosed technology, a method for forming a photoelectric conversion region of an image sensing device may include forming a first mask pattern defining a photoelectric conversion region over a first surface of a substrate, implanting impurities into a first region of the substrate through the first mask pattern, forming a second mask pattern defining the photoelectric conversion region over a second surface opposite the first surface in the substrate, and implanting impurities into a second region of the substrate through the second mask pattern. Each of the first mask pattern and the second mask pattern may be formed to have a minimum thickness that prevents the corresponding impurities from penetrating a material layer of the first mask pattern and a material layer of the second mask pattern when the impurities are implanted into a substrate with the first ion implantation energy using the mask pattern.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

FIG. 1 is a block diagram illustrating an example of an image sensing device based on some implementations of the disclosed technology.

FIG. 2 is a cross-sectional view illustrating an example of a pixel array taken along the line A-A′ shown in FIG. 1 based on some implementations of the disclosed technology.

FIG. 3 is a flowchart illustrating an example of a process for determining information to form a photoelectric conversion region in the structure illustrated in FIG. 2 based on some implementations of the disclosed technology.

FIGS. 4 to 7 are cross-sectional views illustrating an example method for forming a photoelectric conversion region using information determined by the process of FIG. 3 based on some implementations of the disclosed technology.

### DETAILED DESCRIPTION

This patent document provides implementations and examples of an image sensing device that may be used to substantially address one or more technical or engineering issues and mitigate limitations or disadvantages encountered in some other image sensing devices. Some implementations of the disclosed technology suggest examples of a method for uniformly maintaining a critical dimension (CD) of a photoelectric conversion region while deeply forming the photoelectric conversion region. The disclosed technology provides various implementations of a method for forming a photoelectric conversion region of the image sensing device which can minimize a thickness of a substrate and can improve dark characteristics of pixels by making a critical dimension (CD) of the photoelectric conversion region uniform.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

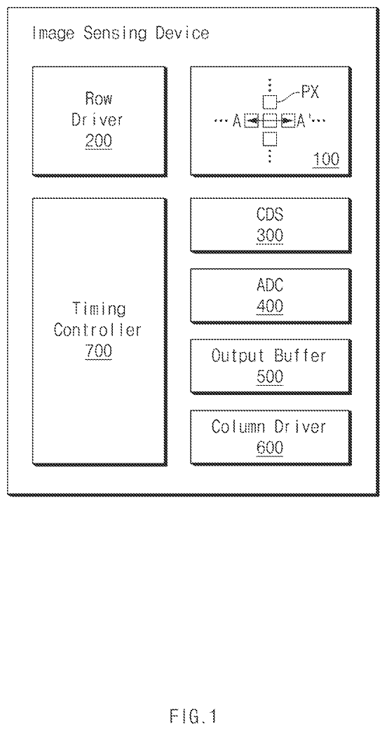

FIG. 1 is a block diagram illustrating an image sensing device based on some implementations of the disclosed technology.

Referring to FIG. 1, the image sensing device may include a pixel array 100, a row driver 200, a correlated double sampler (CDS) 300, an analog-digital converter (ADC) 400, an output buffer 500, a column driver 600, and a timing controller 700. The components of the image sensing device illustrated in FIG. 1 are discussed by way of example only, and this patent document encompasses numerous other changes, substitutions, variations, alterations, and modifications.

The pixel array 100 may include a plurality of unit pixels (PXs) arranged in rows and columns. The plurality of unit pixels (PXs) may convert incident light into an electrical signal (e.g., a pixel signal) corresponding to the incident light by performing photoelectric conversion of the incident light, and may thus output the electrical signal. Each unit pixel (PX) may include a photoelectric conversion region that generates photocharges through photoelectric conversion of the incident light. The photoelectric conversion region of each unit pixel (PX) may be formed to have the same critical dimension (CD) as a whole in a vertical direction. At this time, the critical dimension (CD) of the photoelectric conversion region may refer to a size (e.g., a length in a row direction and a length in a column direction) when viewed in a horizontal plane.

The pixel array 100 may receive driving signals (for example, a row selection signal, a reset signal, a transmission (or transfer) signal, etc.) from the row driver 200. Upon receiving the driving signal, the unit pixels (PXs) may be activated to perform the operations corresponding to the row selection signal, the reset signal, and the transfer signal.

The row driver 200 may activate the pixel array 100 to perform certain operations on the unit pixels in the corresponding row based on control signals provided by controller circuitry such as the timing controller 700. In some implementations, the row driver 200 may select one or more pixel groups arranged in one or more rows of the pixel array 100. The row driver 200 may generate a row selection signal to select one or more rows from among the plurality of rows. The row driver 200 may sequentially enable the reset signal and the transfer signal for the unit pixels arranged in the selected row. The pixel signals generated by the unit pixels arranged in the selected row may be output to the correlated double sampler (CDS) 300.

The correlated double sampler (CDS) 300 may remove undesired offset values of the unit pixels using correlated double sampling. In one example, the correlated double sampler (CDS) 300 may remove the undesired offset values of the unit pixels by comparing output voltages of pixel signals (of the unit pixels) obtained before and after photocharges generated by incident light are accumulated in the sensing node (i.e., a floating diffusion (FD) node). As a result, the CDS 300 may obtain a pixel signal generated only by the incident light without causing noise. In some implementations, upon receiving a clock signal from the timing controller 700, the CDS 300 may sequentially sample and hold voltage levels of the reference signal and the pixel signal, which are provided to each of a plurality of column lines from the pixel array 100. That is, the CDS 300 may sample and hold the voltage levels of the reference signal and the pixel signal which correspond to each of the columns of the pixel array 100. In some implementations, the CDS 300 may transfer the reference signal and the pixel signal of each of the columns as a correlate double sampling (CDS) signal to the ADC 400 based on control signals from the timing controller 700.

The ADC 400 is used to convert analog CDS signals received from the CDS 300 into digital signals. In some implementations, the ADC 400 may be implemented as a ramp-compare type ADC. The analog-to-digital converter (ADC) 400 may compare a ramp signal received from the timing controller 700 with the CDS signal received from the CDS 300, and may thus output a comparison signal indicating the result of comparison between the ramp signal and the CDS signal. The analog-to-digital converter (ADC) 400 may count a level transition time of the comparison signal in response to the ramp signal received from the timing generator 700, and may output a count value indicating the counted level transition time to the output buffer 500.

The output buffer 500 may temporarily store column-based image data provided from the ADC 400 based on control signals of the timing controller 700. The image data received from the ADC 400 may be temporarily stored in the output buffer 500 based on control signals of the timing controller 700. The output buffer 500 may provide an interface to compensate for data rate differences or transmission rate differences between the image sensing device and other devices.

The column driver 600 may select a column of the output buffer 500 upon receiving a control signal from the timing controller 700, and sequentially output the image data, which are temporarily stored in the selected column of the output buffer 500. In some implementations, upon receiving an address signal from the timing controller 700, the column driver 600 may generate a column selection signal based on the address signal, may select a column of the output buffer 500 using the column selection signal, and may control the image data received from the selected column of the output buffer 500 to be output as an output signal.

The timing controller 700 may generate signals for controlling operations of the row driver 200, the ADC 400, the output buffer 500 and the column driver 600. The timing controller 700 may provide the row driver 200, the column driver 600, the ADC 400, and the output buffer 500 with a clock signal required for the operations of the respective components of the image sensing device, a control signal for timing control, and address signals for selecting a row or column. In some implementations, the timing controller 700 may include a logic control circuit, a phase lock loop (PLL) circuit, a timing control circuit, a communication interface circuit and others.

The image sensing device may include a three-dimensional (3D) stack structure in which a first semiconductor layer in which the pixel array 100 is formed and a second semiconductor layer in which the CDS 300, the ADC 400, the output butter 500, the column driver 600, and the timing controller 700 are formed are stacked. Alternatively, the row driver 200, the CDS 300, the ADC 400, the output buffer 500, the column driver 600, and the timing controller 700 may be disposed outside the pixel array 100 within the same semiconductor layer as that of the pixel array 100.

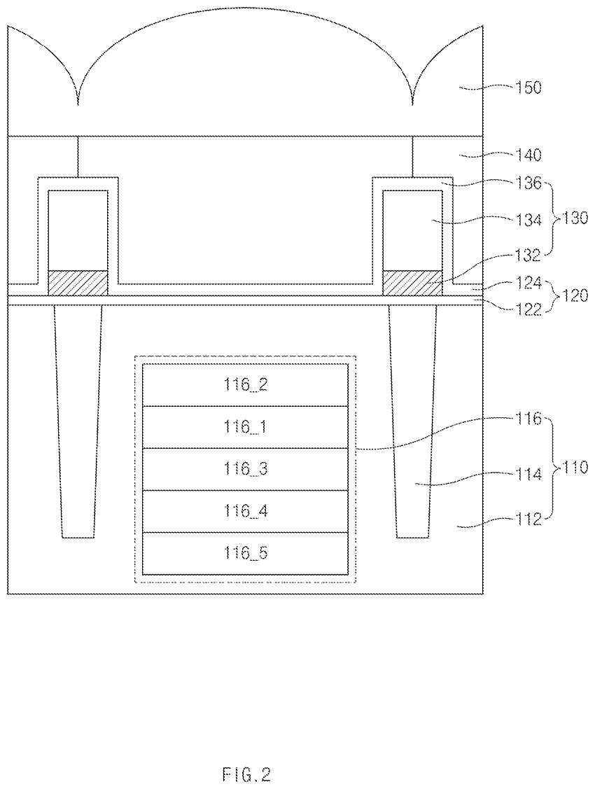

FIG. 2 is a cross-sectional view illustrating an example of the pixel array taken along the line A-A′ shown in FIG. 1 based on some implementations of the disclosed technology.

Referring to FIG. 2, the pixel array 100 of the image sensing device may include a substrate layer 110, a buffer layer 120, a grid structure 130, a color filter layer 140, and a lens layer 150.

The substrate layer 110 may include a substrate 112, a device isolation structure 114, and a photoelectric conversion region 116.

The substrate 112 may include a semiconductor substrate having a first surface and a second surface opposite to the first surface. The first surface of the substrate 112 may be a light reception surface upon which light is incident, and may be formed to have the buffer layer 120, the grid structure 130, the color filter layer 140, and the lens layer 150. The second surface of the substrate 112 may be formed to have pixel transistors that can be used to generate digital data corresponding to photocharges generated by the photoelectric conversion region 116. The semiconductor substrate 112 may include a silicon bulk wafer or an epitaxial wafer. In some implementations, the epitaxial wafer may include a crystalline material layer (e.g., a silicon epitaxial layer) that is formed by an epitaxial growth process on a bulk substrate. In other implementations, the semiconductor substrate 112 may be formed using a variety of wafers different from the bulk wafer or the epitaxial wafer, such as a polished wafer, an annealed wafer, a silicon-on-insulator (SOI) wafer, and others.

The substrate 112 may include P-type impurities, and photoelectric conversion regions 116 corresponding to each unit pixel (PX) may be formed in the substrate 112. The photoelectric conversion regions 116 may generate photocharges by converting light incident upon the first surface of the substrate 112 into electrical signals (photoelectric conversion). The photoelectric conversion regions 116 may be electrically and/or optically isolated by the device isolation structure 114, thereby forming unit pixels PXs. Each of the photoelectric conversion regions 116 may include an organic or inorganic photodiode. A P-type impurity region may be formed between the device isolation structure 114 and the photoelectric conversion regions 116.

The photoelectric conversion region 116 may include a plurality of sub-photoelectric conversion regions 116_1 to 116_5 located at different depths to be vertically stacked in the substrate 112. As illustrated in the example in FIG. 2, the sub-photoelectric conversion regions 116_1 to 116_5 may be formed to have the same critical dimension (CD) when viewed in a plan view. For example, the sub-photoelectric conversion regions 116_1 to 116_5 may be formed to have the same width in the row and column directions. In addition, the sub-photoelectric conversion regions 116_1 to 116_5 may be stacked on top of one another and may be successively arranged in a vertical direction substantially perpendicular to the substrate layer 110 to form one photoelectric conversion region 116. In some implementations, the sub-photoelectric conversion regions 116_1 to 116_5 may be stacked such that the central axes thereof can vertically overlap each other. For example, the photoelectric conversion region 116 may be formed to extend in a vertical direction with a uniform CD.

Although FIG. 2 illustrates five sub-photoelectric conversion regions 116_1 to 116_5 successively connected to form one photoelectric conversion region 116 by way of example, it should be noted that the number of sub-photoelectric conversion regions may vary. In addition, although FIG. 2 shows the sub-photoelectric conversion regions 116_1 to 116_5 as having the same height, the heights of the sub-photoelectric conversion regions 116_1 to 116_5 may be different in certain implementations.

In some implementations, the photoelectric conversion region 116 may have an overall uniform CD as will be discussed below.

The sub-photoelectric conversion regions 116_1 to 116_5 may be formed in the semiconductor substrate 112 through an ion implantation process. For example, when the semiconductor substrate 142 is based on the P-type epitaxial wafer, N-type impurities may be implanted into the sub-photoelectric conversion regions 116_1 to 116_5.

The device isolation structure 114 may be disposed between adjacent photoelectric conversion regions 116 to electrically isolate the photoelectric conversion regions 116 from each other. The device isolation structure 114 may include an insulation material that is buried in a trench. For example, the device isolation structure 114 may include a deep trench isolation (DTI) structure. Alternatively, the device isolation structure 114 may include high-density insulation impurities that are implanted into the semiconductor substrate 112.

The buffer layer 120 may be used as a planarization layer to remove surface topologies on the second surface of the substrate 112. In addition, the buffer layer 120 may operate as an anti-reflection layer to allow incident light received through the lens layer 150 and the color filters 140 to pass through the photoelectric conversion region 116. The buffer layer 120 may include a multilayer structure formed by stacking different material layers having different refractive indices. For example, the buffer layer 120 may include a multilayer structure formed by stacking at least one nitride film 122 and at least one oxide film 124.

The nitride film 122 may include a silicon nitride film (SiₓN_{y}, where x and y are natural numbers) or a silicon oxide nitride film (SiₓO_{y}N_{z}, where x, y, and z are natural numbers). The oxide film 124 may include a monolayer structure formed of any one of an Undoped Silicate Glass (USG) film and an Ultra-Low Temperature Oxide (ULTO) film, or may include a multilayer structure formed by stacking the USG film and the ULTO film. The oxide film 124 may include the same material as the capping layer 136 of the grid structure 143, and the oxide film 124 and the capping layer 136 may be simultaneously formed through the same deposition process.

In addition, a fixed charge layer (not shown) may be formed below the nitride film 122 to prevent hole (electron hole) accumulation from occurring in the substrate 112. The fixed charge layer may include a metal oxide material such as aluminum oxide (Al₂O₃), tantalum oxide (Ta₂O₅), titanium oxide (TiO₂), and others.

Each grid structure 130 may be disposed between the adjacent color filters 140, and may prevent optical crosstalk from occurring between the color filters 140. The grid structure 130 may include a metal layer 132, an air layer 134, and a capping layer 136. The capping layer 136 may be a material film formed at an outermost part of the grid structure 130, and may cover the air layer 134. The capping layer 136 may be formed to extend to a lower portion of the color filter layer 140. In this case, the capping layer formed below the color filter layer 140 may be used as the oxide film 124 of the buffer layer 120.

The color filter layer 140 may include color filters that are located on the buffer layer 120. In some implementations, each unit pixel (PX) includes a color filter formed on the buffer layer 120. The color filters may be located in a region defined by the grid structure 130. The color filter layer 140 may include a plurality of red color filters (Rs), a plurality of green color filters (Gs), and a plurality of blue color filters (Bs). Each red color filter (R) may transmit only red light and absorb other colors. Each green color filter (G) may transmit only green light and absorb other colors. Each blue color filter (B) may transmit only blue light and absorb other colors.

The lens layer 150 may be disposed over the color filter layer 140. The lens layer 150 may direct (or guide) incident light to the photoelectric conversion region 116 of each unit pixel (PX). The lens layer 150 may converge the incident light and transmit the converged light to the color filter layer 140. The lens layer 150 may include an over-coating layer, a microlens layer, and an anti-reflection layer. The over-coating layer may be disposed below the microlens layer to prevent irregular or diffused reflection of incident light that would have caused flare and to surface topologies of the color filters. The microlens layer may be disposed over the over-coating layer, and may be formed in a hemispherical shape to converge incident light. The anti-reflection layer may be disposed over the microlens layer, and may prevent incident light from being reflected by the microlens layer while protecting the microlens layer.

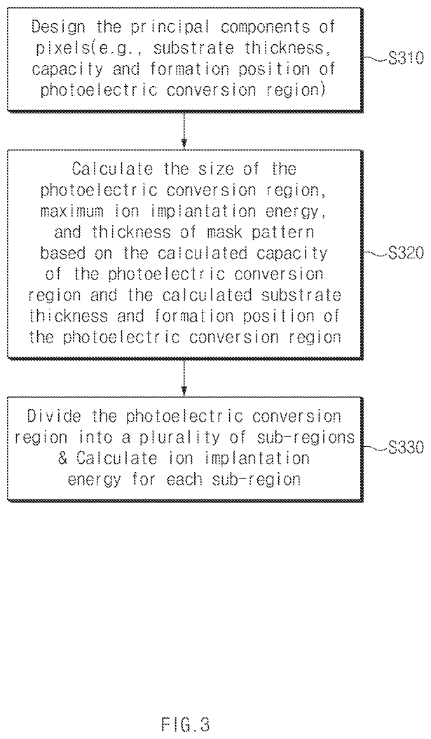

FIG. 3 is a flowchart illustrating a method for calculating information required to form the photoelectric conversion region in the cross-sectional structure of FIG. 2 based on some implementations of the disclosed technology.

Referring to FIG. 3, a design system (not shown) may design components of pixels that can meet the requirements for pixel performance of an image sensor to be manufactured (S310).

For example, the design system may calculate, for example, a substrate thickness, a full well capacity (FWC) and a formation position of a photoelectric conversion region, a transfer capacity of the transfer transistor, which are required to manufacture the image sensor having a desired performance. In this case, the substrate thickness may refer to the thickness of a substrate in which the photoelectric conversion region is to be formed. Pixel performance required for the image sensor may be preset and configured in the design system by a system designer.

The design system may calculate the size (e.g., a critical dimension (CD) and a height) of a photoelectric conversion region to be formed, a maximum ion implantation energy, and a thickness of a mask pattern corresponding to the maximum ion implantation energy, based on the capacity of the photoelectric conversion region and the substrate thickness which have been determined/calculated at S310 (S320).

For example, in order for the photoelectric conversion region to have an overall uniform CD in a vertical direction and to have the capacity determined/calculated at S310, the design system may calculate the CD of the photoelectric conversion region to be formed, and the position and height of the photoelectric conversion region to be formed. In this case, the CD of the photoelectric conversion region may include a width in the row direction and a width in the column direction when viewed in a plan view.

In addition, the design system may calculate the maximum energy (maximum ion implantation energy) for implanting impurities into the photoelectric conversion region and the thickness of the mask pattern corresponding to the maximum ion implantation energy, based on the substrate thickness and the formation position and height of the photoelectric conversion region. For example, the design system may calculate a maximum value (i.e., the maximum ion implantation energy) of the ion implantation energy required when the impurities are implanted at a position in the substrate corresponding to ½ of the substrate thickness determined at S310.

When the maximum ion implantation energy is determined, the design system may calculate the thickness (i.e., a minimum thickness) of the mask pattern to prevent the impurities from penetrating a material layer of the mask pattern even if the impurities are implanted with the maximum ion implantation energy.

For example, when a photoresist pattern is used as a mask pattern for impurity implantation, some impurities may be introduced into the substrate after passing through the photoresist layer during the impurity implantation process. As such, the impurities introduced into the substrate after passing through the photoresist layer are mainly concentrated near the surface of the substrate, and such impurities may affect the operation characteristics of the pixel. For example, the impurities introduced onto the surface of the substrate after passing through the photoresist layer may degrade the dark characteristics of the pixel. Therefore, during the impurity implantation process, the photoelectric conversion region is formed by implanting the corresponding impurities into the substrate only through the open region of the photoresist pattern without penetrating the photoresist layer.

In order to prevent impurities from penetrating the photoresist layer, the ion implantation energy is set low or the thickness of the photoresist pattern is increased to a sufficiently large thickness so that the penetration through the photoresist layer by the implanted impurities is minimized below a desired level or substantially eliminated. However, it is difficult to form the photoelectric conversion region deep in the substrate by using such a low ion implantation energy. In addition, when the thickness of the photoresist pattern is increased, it is difficult to pattern the photoresist layer in a desired shape or pattern and accurately control the CD of the photoelectric conversion region, causing deviation between pixels.

In some embodiments of the disclosed technology, in order to form a thin photoresist pattern and form the photoelectric conversion region having a uniform CD at a deep depth in the substrate, the maximum ion implantation energy may be determined based on the position or depth in the substrate corresponding to ½ of the substrate thickness, and the thickness of the photoresist pattern corresponding to the maximum ion implantation energy may be determined.

In addition, the design system may divide the photoelectric conversion region into a plurality of sub-regions (e.g., a plurality of sub-photoelectric conversion regions), and may calculate the ion implantation energy for each sub-photoelectric conversion region (S330).

Impurity implantation with the same ion implantation energy over the entire photoelectric conversion region may render the CD of the photoelectric conversion region non-uniform, and thus the design system based on the disclosed technology uses different levels of implanting energy for forming different adjacent sub regions at different depths from the substrate surface so that those different adjacent sub regions at different depths collectively form the desired contiguous photoelectric conversion region. Therefore, instead of designing the photomask and the implanting energy for implanting impurities to form the desired final the photoelectric conversion region in a substrate in one single implantation process at the same implantation energy level, the disclosed technology divides the desired photoelectric conversion region into a plurality of different and adjacent sub-photoelectric conversion regions at different depths from the substrate surface in the vertical direction perpendicular to the substrate and forming those sub-photoelectric conversion regions at different depths using different implanting steps at different implanting energy levels by using a thinner mask pattern that the mask matter needed for the one single implantation process. This multi-step implanting process involves determination of different desired ion implantation energy levels for the different sub-photoelectric conversion regions at different depths. For example, the design system may divide the photoelectric conversion region into an upper region and a lower region based on a specific position or depth in the substrate corresponding to ½ of the substrate thickness, and may divide each of the upper region and the lower region into at least one sub-photoelectric conversion region. The implanting process can be performed in different processes at different energy levels less than the maximum energy level and can further reduce the implantation energy and the thickness of the mask pattern by performing the implanting of impurities from two opposite surfaces of the substrate. In some implementations, the ion implantation energy for each sub-photoelectric conversion region and the height of each sub-photoelectric conversion region may have specific values such that the sub-photoelectric conversion regions have the same CD value.

As shown in FIG. 2 by way of example, the photoelectric conversion region 116 is divided into five sub-photoelectric conversion regions 116_1 to 116_5, and, in some implementations, the sub-photoelectric conversion regions 116_1 to 116_5 may have the same height.

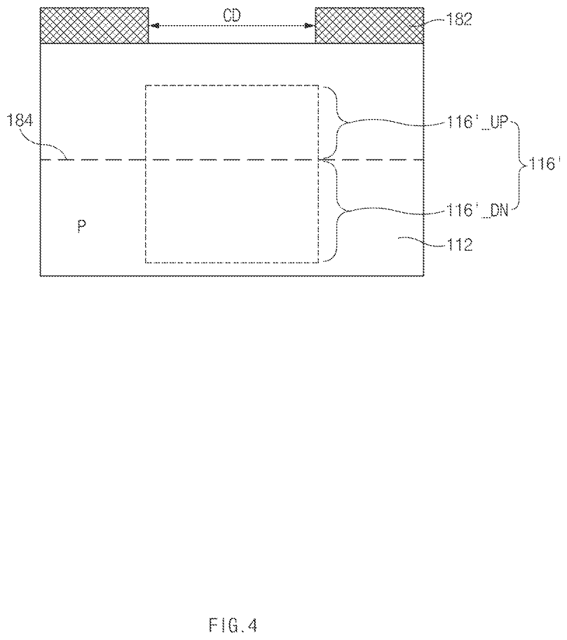

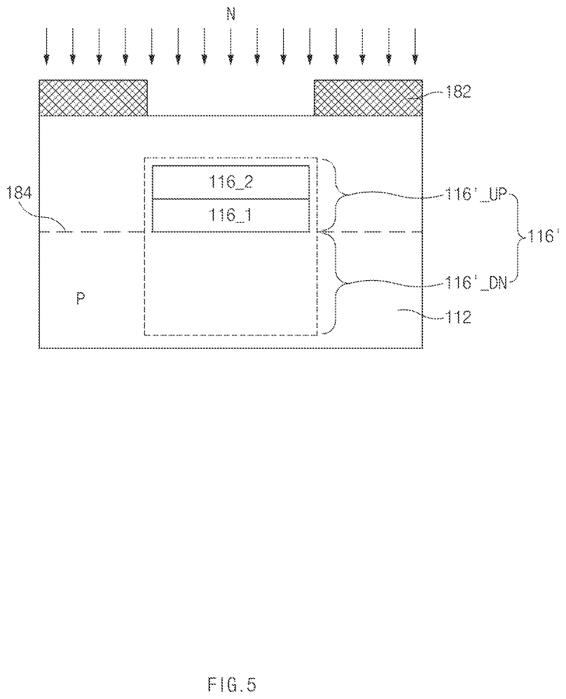

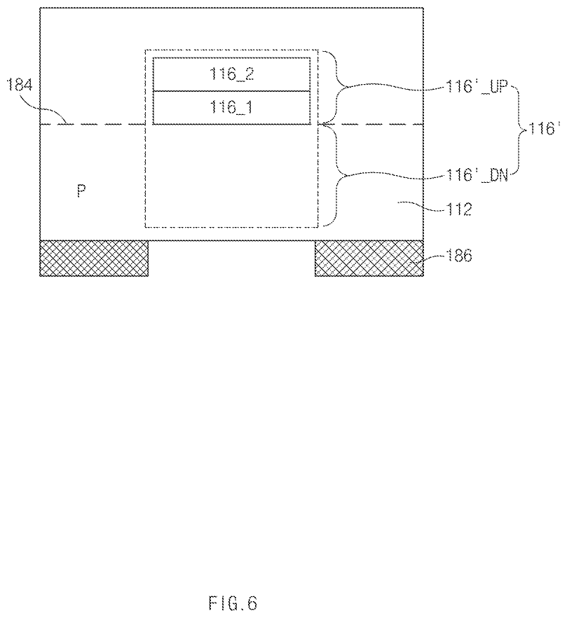

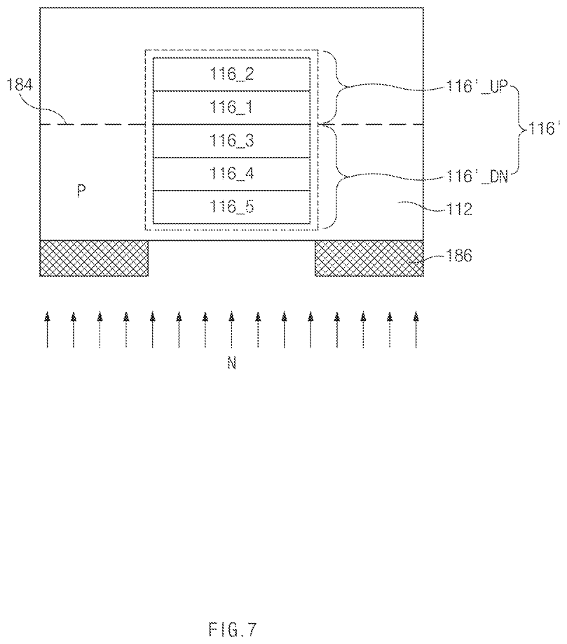

FIGS. 4 to 7 are cross-sectional views illustrating example method for forming the photoelectric conversion region using information determined by the method of FIG. 3 based on some implementations of the disclosed technology. In this example, FIGS. 4 and 5 show implanting via the first top surface of the substrate 112 for forming sub-photoelectric conversion regions closer to the first top surface and FIGS. 6 and 7 show implanting via the second bottom surface of the substrate 112 for forming sub-photoelectric conversion regions closer to the second bottom surface.

Referring to FIG. 4, a mask pattern 182 for defining a specific region (hereinafter referred to as a predetermined photoelectric conversion region) 116′ that will be formed as a photoelectric conversion region in a subsequent fabrication process may be formed over the first surface of the substrate 112 having a thickness calculated at S310. In some implementations, the size (i.e., the row-directional width and the column-directional width) of the open region of the mask pattern 182 may be set to the CD of the photoelectric conversion region determined at S320 in FIG. 3.

The substrate 112 may include a bulk silicon wafer including P-type impurities, or an epitaxial wafer. The substrate 112 may include a first surface and a second surface opposite the first surface. The mask pattern 182 may include a photoresist pattern. As an example, the thickness of the photoresist pattern 182 may be equal to the thickness of the mask pattern determined at S320 in FIG. 3. That is, the photoresist pattern 182 may be formed to have a thickness such that impurities are not introduced into the substrate 112 through the photoresist layer of the photoresist pattern 182 even when the impurities are implanted with the maximum ion implantation energy determined at S320 in FIG. 3.

The predetermined photoelectric conversion region 116′ may include an upper region (116′_UP) located close to the first surface of the substrate 112 and a lower region (116′_DN) located close to the second surface of the substrate 112 with respect to the center line (or half-substrate depth) in the substrate 184 corresponding to ½ of the substrate thickness.

Referring to FIG. 5, N-type impurities are implanted through the first (top) surface of the substrate 112, so that the sub-photoelectric conversion regions 116_1 and 116_2 may be sequentially formed in the upper region (116′_UP) of the predetermined photoelectric conversion region 116′. For example, the first sub-photoelectric conversion region 116_1 close to the center line 184 may be formed first in the upper region (116′_UP) of the photoelectric conversion region 116′. Subsequently, a second sub-photoelectric conversion region 116_2 immediately above and in contact with the first sub-photoelectric conversion region 116_1 may be formed next by using the same mask pattern 182. Since the second sub-photoelectric conversion region 116_2 is immediately above the first sub-photoelectric conversion region 116_1 and thus is closer to the first (top) surface of the substrate 112 than the first sub-photoelectric conversion region 116_1, the additional implanting of N-type impurities into the upper region (116′_UP) for forming the shallower second sub-photoelectric conversion region 116_2 can be achieved by using an implantation energy level smaller than the implantation energy level that is used to form the first sub-photoelectric conversion region 116_1. The second sub-photoelectric conversion region 116_2 may have the same CD as the first sub-photoelectric conversion region 116_1.

Therefore, the energy for implanting impurities into the first sub-photoelectric conversion region 116_1 may be equal to or smaller than the maximum ion implantation energy. Therefore, when impurities (N-type impurities) are implanted into the first sub-photoelectric conversion region 116_1, few or no impurities can penetrate the material layer of the mask pattern 182, and thus few or no impurities are present around the first surface of the substrate 112. Further, since the second sub-photoelectric conversion region 116_2 is located closer to the first surface of the substrate 112 than the first sub-photoelectric conversion region 116_1, impurities may be implanted for forming the second sub-photoelectric conversion region 116_2 with an ion implanting energy level smaller than the energy that is used to implant impurities into the first sub-photoelectric conversion region 116_1. Therefore, even when impurities are implanted into the second sub-photoelectric conversion region 116_2, the impurities targeted at the second sub-photoelectric conversion region 116_2 generally are not sufficiently energic to penetrate the material layer of the mask pattern 182.

Referring to FIG. 6, after finishing formation of the first sub-photoelectric conversion region 116_1 and second sub-photoelectric conversion region 116_2 in the upper region (116′_UP) by using the mask pattern 182, the mask pattern 182 formed over the first surface of the substrate 112 may be removed, and a mask pattern 186 defining a photoelectric conversion region 116′ may be formed over a second surface of the substrate 112 for forming sub-photoelectric conversion regions by impurity implanting from the second (bottom) surface of the substrate 112.

Similarly to the formation of the first sub-photoelectric conversion region 116_1 and second sub-photoelectric conversion region 116_2 in the upper region (116′_UP), the size (e.g., width in the row direction and the width in the column direction) of the open region of the mask pattern 186 may be the CD of the photoelectric conversion region determined at S320 in FIG. 3. The mask pattern 186 may include a photoresist pattern, and the thickness of the photoresist pattern 186 may be a thickness of the mask pattern determined at S320 of FIG. 3. For example, the mask pattern 186 may be formed to have the same thickness as the mask pattern 182.

Referring to FIG. 7, N-type impurities are implanted through the second (bottom) surface of the substrate 112 so that the sub-photoelectric conversion regions 116_3 to 116_5 are sequentially formed in the lower region 116′_DN of the photoelectric conversion region 116′ to jointly form the photoelectric conversion region 116 with the first sub-photoelectric conversion region 116_1 and second sub-photoelectric conversion region 116_2 in the upper region (116′_UP). For example, the third sub-photoelectric conversion region 116_3 close to the center line 184 may be formed first in the lower region 116′_DN of the photoelectric conversion region 116′. Subsequently, a fourth sub-photoelectric conversion region 116_4 connected to the third sub-photoelectric conversion region 116_3 may be formed by using the same mask pattern 186 and additionally implanting N-type impurities into the lower region 116′_DN with energy smaller than the energy that is used to form the third sub-photoelectric conversion region 116_3. Thereafter, a fifth sub-photoelectric conversion region 116_5 connected to the fourth sub-photoelectric conversion region 116_4 may be formed by using the same mask pattern 186, and additionally implanting N-type impurities into the lower region 116′_DN with energy smaller than the energy that is used to form the fourth sub-photoelectric conversion region 116_4. Since the first to fifth sub-photoelectric conversion regions 116_1 to 116_5 have the same CD, the photoelectric conversion region 116 formed by stacking the first to fifth sub-photoelectric conversion regions 116_1 to 116_5 may have an overall uniform CD.

In this case, the energy for implanting impurities into the third sub-photoelectric conversion region 116_3 may be equal to or smaller than the maximum ion implantation energy. Therefore, when impurities are implanted into the third sub-photoelectric conversion region 116_3, few or no impurities can penetrate the material layer of the mask pattern 186, and thus be few or no impurities are present around the second surface of the substrate 112. Further, since the fourth and fifth sub-photoelectric conversion regions 116_4 and 116_5 are located closer to the second surface of the substrate 112 than the third sub-photoelectric conversion region 116_3, impurities may be implanted with energy smaller than the energy that is used to implant impurities into the third sub-photoelectric conversion region 116_3. Therefore, even when impurities are implanted into the fourth and fifth sub-photoelectric conversion regions 116_4 and 116_5, the impurities do not penetrate the material layer of the mask pattern 186.

As is apparent from the above description, in forming a photoelectric conversion region of the image sensing device, the disclosed technology can be implemented in some embodiments to minimize a thickness of a substrate and the uniform critical dimension (CD) of the photoelectric conversion region can reduce or minimize dark current in pixels.

Some embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. A method for forming a photoelectric conversion region of an image sensing device comprising:
determining a thickness of a substrate and a capacitance of a photoelectric conversion region of an image sensing pixel corresponding to a desired performance of the image sensing pixel;
determining a size of a desired photoelectric conversion region for the image sensing pixel based on the determined thickness of the substrate and the determined capacitance of the photoelectric conversion region;
determining a first ion implantation energy suitable for implanting impurities into a predetermined depth in the substrate;
determining a thickness of a mask pattern corresponding to the first ion implantation energy; and
determining at least one second ion implantation energy suitable for implanting the impurities into the substrate for forming a plurality of sub-photoelectric conversion regions at different depths that collectively form the desired photoelectric conversion region.

2. The method according to claim 1, wherein:
the first ion implantation energy is a maximum ion implantation energy to implant impurities at a position in the photoelectric conversion region corresponding to ½ of the substrate thickness.

3. The method according to claim 1, wherein the determining the size of the photoelectric conversion region includes:
determining a critical dimension (CD) and a height of the photoelectric conversion region to have a uniform CD throughout the photoelectric conversion region in a vertical direction and to obtain the capacity of the photoelectric conversion region at the determined CD and height.

4. The method according to claim 1, wherein the determining the thickness of the mask pattern comprises:
determining a minimum thickness of the mask pattern that prevents the impurities from penetrating a material layer of the mask pattern when the impurities are implanted into the substrate at the first ion implantation energy using the mask pattern as an implantation mask.

5. A method for forming a photoelectric conversion region of an image sensing device comprising:
forming a first mask pattern defining a photoelectric conversion region over a first surface of a substrate;
implanting impurities from the first surface of the substrate into a first region in the substrate using the first mask pattern as an implantation mask;
forming a second mask pattern defining the photoelectric conversion region over a second surface opposite to the first surface of the substrate; and
implanting impurities from the second surface of the substrate into a second region in the substrate using the second mask pattern as an implantation mask,
wherein each of the first mask pattern and the second mask pattern is formed to have a minimum thickness that prevents the corresponding impurities from penetrating a material layer of the first mask pattern and a material layer of the second mask pattern when the impurities are implanted into the substrate at a first ion implantation energy using the first mask pattern and the second mask pattern as implantation masks, respectively.

6. The method according to claim 5, wherein:
each of a size of an open region of the first mask pattern and a size of an open region of the second mask pattern is the same as a critical dimension (CD) of the photoelectric conversion region.

7. The method according to claim 5, wherein:
the first ion implantation energy is a maximum ion implantation energy to implant impurities into a region in the photoelectric conversion region corresponding to ½ of a thickness of the substrate.

8. The method according to claim 5, wherein:
the first region includes a region that extends from a half-substrate depth in the substrate toward the first surface of the substrate; and
the second region is a region that extends from the half-substrate depth in the substrate toward the second surface of the substrate.

9. The method according to claim 8, wherein:
the first region and the second region are in contact with each other at the half-substrate depth in the substrate such that a central vertical axis of the first region and a central vertical axis of the second region overlap each other.

10. The method according to claim 8, wherein the implanting the impurities into the first region includes:
implanting impurities at a second ion implantation energy into a first sub-photoelectric conversion region in contact with the half-substrate depth in the substrate; and
implanting impurities at a third ion implantation energy smaller than the second ion implantation energy into a second sub-photoelectric conversion region that is disposed above the first sub-photoelectric conversion region and in contact with the first sub-photoelectric conversion region.

11. The method according to claim 10, wherein the implanting the impurities into the second region includes:
implanting impurities at the second ion implantation energy into a third sub-photoelectric conversion region in contact with the half-substrate depth in the substrate; and
implanting impurities at the third ion implantation energy into a fourth sub-photoelectric conversion region that is disposed above the third sub-photoelectric conversion region and in contact with the third sub-photoelectric conversion region.

12. The method according to claim 5, further comprising:
determining a thickness of the substrate and a capacitance of the photoelectric conversion region of the image sensing pixel corresponding to a desired performance of the image sensing pixel;
determining a size of the photoelectric conversion region based on the determined thickness of the substrate and the determined capacitance of the photoelectric conversion region;
determining the first ion implantation energy suitable for implanting impurities into a predetermined depth in the substrate; and
determining a thickness of the first and second mask patterns corresponding to the first ion implantation energy; and
dividing the photoelectric conversion region into a plurality of sub-photoelectric conversion regions arranged on top of one another, and determining at least one second ion implantation energy required to implant the impurities into the plurality of sub-photoelectric conversion regions.

13. The method according to claim 12, wherein:
the first ion implantation energy is a maximum ion implantation energy to implant impurities at a position in the photoelectric conversion region corresponding to ½ of the substrate thickness.

14. The method according to claim 12, wherein the determining the size of the photoelectric conversion region includes:
determining a critical dimension (CD) and a height of the photoelectric conversion region to have a uniform CD throughout the photoelectric conversion region in a vertical direction and to obtain the capacity of the photoelectric conversion region at the determined CD and height.

15. The method according to claim 12, wherein the determining the thickness of the first and second mask patterns comprises:
determining a minimum thickness of the first and second mask patterns that prevents the impurities from penetrating a material layer of the first and second mask patterns when the impurities are implanted into the substrate at the first ion implantation energy using the first and second mask patterns as implantation masks.
